(19) United States
(12) Patent Application Publication
(10) Pub. No.: US 2013/0105978 A1
(43) Pub. Date: May 2, 2013

(54) SILICON SUBMOUNT FOR LIGHT EMITTING DIODE AND METHOD OF FORMING THE SAME

(71) Applicant: Chih-Lung Hung, Hsinchu City (TW)

(72) Inventor: Chih-Lung Hung, Hsinchu City (TW)

(73) Assignee: EPISIL TECHNOLOGIES INC., Hsinchu City (TW)

(21) Appl. No.: 13/337,159

(22) Filed: Dec. 26, 2011

(30) Foreign Application Priority Data
Oct. 26, 2011 (TW) 100138925

(51) Int. Cl. H01L 23/532; H01L 21/768

(52) U.S. Cl. 257/751; 438/653; 257/E23.155; 257/E21.584

(57) ABSTRACT

A silicon submount for a light emitting diode (LED) including a silicon base, a first insulating layer, a first electrode, a second electrode, and a reflective layer is provided. The silicon base has an upper surface and a lower surface, and a recess is disposed at the upper surface. The first insulating layer covers the upper surface and the lower surface of the silicon base. The first electrode and the second electrode are disposed on the first insulating layer on a bottom of the recess. The reflective layer is disposed on the first insulating layer on a sidewall of the recess. The first electrode, the second electrode, and the reflective layer are separated from one another and formed by the same material.

### CROSS-REFERENCE TO RELATED APPLICATION

This application claims the priority benefit of Taiwan application serial no. 100138925, filed on Oct. 26, 2011. The entirety of the above-mentioned patent application is hereby incorporated by reference herein and made a part of this specification.

### BACKGROUND OF THE INVENTION

1. Field of the Invention

The invention relates to a semiconductor component and a method of forming the same. More particularly, the invention relates to a silicon submount for a light emitting diode (LED) and a method of forming the same.

2. Description of Related Art

The mechanism of a light emitting diode (LED) relates to light emission resulting from the energy that is released when electrons and holes in a semiconductor material are combined. Due to numerous advantages of the LED including compact volume, durability, low driving voltages, low electricity consumption, fast response speed, great resistance to vibration, and favorable monochromaticity, the LED that serves as a light emitting device is often applied in various electronic products, information billboards, and communication products.

Generally, in an LED package structure, an LED chip is disposed in a recess of a submount. The submount is often made of a resin material (e.g., epoxy resin), and the resin material exposed to ultraviolet radiation over a long period is very much likely to encounter problems of degeneration or friability. Thereby, the life span of the LED package is significantly reduced, and so is the applicability of the LED package in certain fields.

In addition, when the LED operates with a large current, the requirement of the submount for heat dissipation increases accordingly. The submount with great heat dissipation capacity allows the light extraction efficiency of the LED to be enhanced, and the quantum efficiency of the liquid emitting layer in the LED is not reduced because of the overly-heated device. As a result, a submount characterized by both insulation property and heat dissipation capacity has drawn attention of the industry.

### SUMMARY OF THE INVENTION

The invention is directed to a silicon submount of a light emitting diode (LED) that is characterized by both insulation property and heat dissipation capacity. Besides, the silicon submount can reduce the light loss of the LED.

The invention is further directed to a method of forming the silicon submount. The method has simplified manufacturing steps and can be performed with reduced costs.

In the invention, a silicon submount for an LED includes a silicon base, a first insulating layer, a first electrode, a second electrode, and a reflective layer. The silicon base has an upper surface and a lower surface, and a recess is located at the upper surface. The first insulating layer covers the upper surface and the lower surface of the silicon base. The first electrode and the second electrode are disposed on the first insulating layer on a bottom of the recess. The reflective layer is disposed on the first insulating layer on a sidewall of the recess. The first electrode, the second electrode, and the reflective layer are separated from one another and formed by the same material.

According to an embodiment of the invention, a thermal conductivity of the first insulating layer is greater than about 15 W/mk.

According to an embodiment of the invention, a material of the first insulating layer includes aluminum oxide, aluminum nitride, or silicon nitride.

According to an embodiment of the invention, the material of the first electrode, the material of the second electrode, and the material of the reflective layer include silver.

According to an embodiment of the invention, the silicon submount for the LED further includes a barrier metal layer disposed between the silicon base and the first electrode, between the silicon base and the second electrode, and between the silicon base and the reflective layer.

According to an embodiment of the invention, a material of the barrier metal layer includes titanium tungsten/copper (TiW/Cu).

According to an embodiment of the invention, the silicon submount for the LED further includes a second insulating layer disposed on an outer sidewall of the silicon base.

According to an embodiment of the invention, a material of the first insulating layer is different from a material of the second insulating layer.

In the invention, a method of forming a silicon submount for an LED is further provided. According to the method, a silicon substrate having an upper surface and a lower surface is provided. A plurality of recesses are formed at the upper surface of the silicon substrate. A first insulating layer is formed on the upper surface and the lower surface of the silicon substrate. A metal layer is formed on the upper surface of the silicon substrate. The metal layer is patterned to form a first electrode and a second electrode on the first insulating layer on a bottom of each of the recesses and to form a reflective layer on the first insulating layer on a sidewall of each of the recesses.

According to an embodiment of the invention, a thermal conductivity of the first insulating layer is greater than about 15 W/mk.

According to an embodiment of the invention, a material of the first insulating layer includes aluminum oxide, aluminum nitride, or silicon nitride.

According to an embodiment of the invention, a method of forming the first insulating layer includes performing a low pressure chemical vapor deposition (LPCVD) process or a sputtering process.

According to an embodiment of the invention, after the metal layer is patterned, the method of forming the silicon submount for the LED further includes performing a cutting process on the silicon substrate to form a plurality of silicon bases and coating a second insulating layer on an outer sidewall of each of the silicon bases.

According to an embodiment of the invention, a material of the first insulating layer is different from a material of the second insulating layer.

According to an embodiment of the invention, a method of forming the metal layer includes performing a multi-step plating process.

According to an embodiment of the invention, a material of the metal layer includes silver.

According to an embodiment of the invention, after the first insulating layer is formed and before the metal layer is formed, the method of forming the silicon submount for the LED further includes forming a barrier metal material layer on the upper surface of the silicon substrate.

According to an embodiment of the invention, a material of the barrier metal material layer includes TiW/Cu.

Based on the above, in the silicon submount described in the embodiments of the invention, a material with favorable thermal conductivity (e.g., aluminum oxide, aluminum nitride, or aluminum silicon) is applied to cover the upper surface and the lower surface of the silicon base. Since the thermal conductivity of aluminum oxide, aluminum nitride, or aluminum silicon is greater than that of the conventional silicon oxide material, using aluminum oxide, aluminum nitride, or aluminum silicon is beneficial for heat dissipation of the device, and thus, the device performance is improved. In addition, the method of forming the submount for the LED is simple, and a silver material with high reflectivity is applied to simultaneously define the first electrode, the second electrode, and the reflective layer, so as to simplify the manufacturing process, lower the manufacturing costs, and reduce the light loss of the LED.

Several exemplary embodiments accompanied with figures are described in detail below to further describe the invention in details.

### BRIEF DESCRIPTION OF THE DRAWINGS

The accompanying drawings are included to provide a further understanding of the disclosure, and are incorporated in and constitute a part of this specification. The drawings illustrate exemplary embodiments of the invention and, together with the description, serve to explain the principles of the invention.

FIG. 1A to FIG. 1D are schematic cross-sectional views illustrating a method of forming a silicon submount for an LED according to an embodiment of the invention.

FIG. 2 is a schematic cross-sectional view illustrating an LED package structure according to an embodiment of the invention.

### DETAILED DESCRIPTION OF DISCLOSED EXEMPLARY EMBODIMENTS

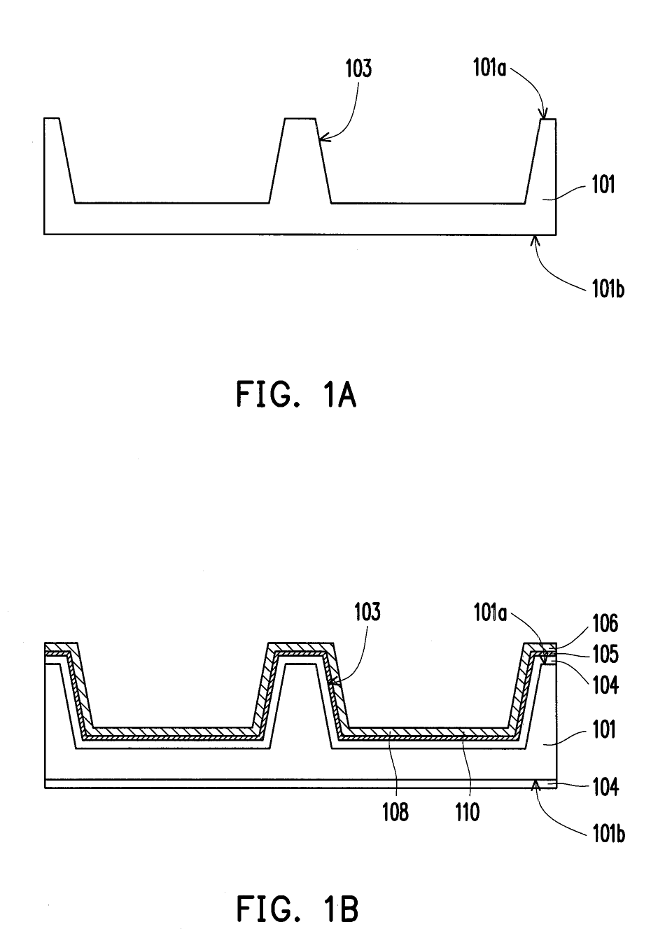

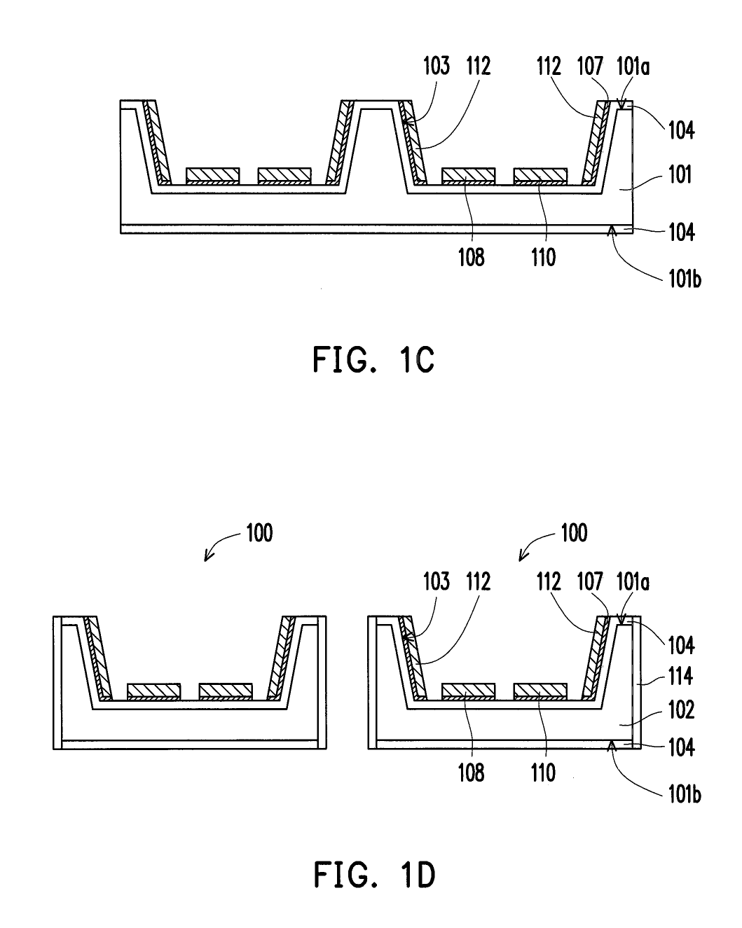

FIG. 1A to FIG. 1D are schematic cross-sectional views illustrating a method of forming a silicon submount for an LED according to a first embodiment of the invention.

With reference to FIG. 1A, a silicon substrate 101 is provided. The silicon substrate 101 has an upper surface 101a and a lower surface 101b. A plurality of recesses 103 are formed at the upper surface 101a of the silicon substrate 101. Each recess 103 has an inclined sidewall, for instance. Steps of forming the recess 103 are described below. First, an oxide pad layer, a silicon nitride layer, and a patterned photoresist layer (not shown) are sequentially formed on the upper surface 101a of the silicon substrate 101. An etching process is performed with use of the patterned photoresist layer as a mask, so as to form a patterned oxide pad layer and a patterned silicon nitride layer. The patterned photoresist layer is removed. A wet etching process is performed with use of the patterned oxide pad layer and the patterned silicon nitride layer as a mask, so as to form a plurality of recesses 103 at the upper surface 101a of the silicon substrate 101. Here, a potassium hydroxide (KOH) solution is exemplarily employed in the wet etching process. The patterned pad oxide layer and the patterned silicon nitride layer are then removed.

With reference to FIG. 1B, a first insulating layer 104 is formed on the upper surface 101a and the lower surface 101b of the silicon substrate 101. The thermal conductivity of the first insulating layer 104 is greater than about 15 W/mk, for instance. A material of the first insulating layer 104 is, for instance, aluminum oxide (with the thermal conductivity of about 22-32 W/mk), aluminum nitride (with the thermal conductivity of about 160-200 W/mk), or silicon nitride (with the thermal conductivity of about 16-33 W/mk). According to an embodiment of the invention, when the first insulating layer 104 is an aluminum oxide layer or an aluminum nitride layer, a method of forming the aluminum oxide layer or the aluminum nitride layer includes performing a sputtering process. According to another embodiment of the invention, when the first insulating layer 104 is a silicon nitride layer, a method of forming the silicon nitride layer includes performing a low pressure chemical vapor deposition (LPCVD) process.

It should be mentioned that the conventional insulating material refers to silicon oxide in most cases. Since the thermal conductivity of silicon oxide is merely 1.4 W/mk, the heat dissipation capacity of silicon oxide is not satisfactory. By contrast, the thermal conductivity of the first insulating layer 104 is greater than 15 W/mk (at least 10 times the conventional silicon oxide material), and thus the heat dissipation capacity of the silicon submount can be significantly improved according to the embodiment of the invention.

A barrier metal material layer 105 and a metal layer 106 are sequentially formed on the upper surface 101a of the silicon substrate 101. A method of forming the barrier metal material layer 105 is, for instance, performing a sputtering process, and the barrier metal material layer 105 is made of titanium tungsten/copper (TiW/Cu), for instance. A material of the metal layer 106 is silver (Ag), for instance. A method of forming the metal layer 106 is, for instance, performing a multi-step plating process. Specifically, the metal layer 106 formed through the multi-step plating process includes a plurality of metal sublayers. By gradually stacking the metal sublayers one by one, the metal layer 106 may become more even and smoother.

With reference to FIG. 1C, the metal layer 106 is patterned to form a first electrode 108 and a second electrode 110 on the first insulating layer 104 on a bottom of each of the recesses 103 and to form a reflective layer 112 on the first insulating layer 104 on a sidewall of each of the recesses 103. The first electrode 108, the second electrode 110, and the reflective layer 112 are separated from one another. Here, the first electrode 108 and the second electrode 110 respectively serve as the positive electrode and the negative electrode, for instance. Besides, in the above-mentioned patterning step, the barrier metal material layer 105 can be patterned as well, so as to form a barrier metal layer 107 between the silicon substrate 101 and the first electrode 108, between the silicon substrate 101 and the second electrode 110, and between the silicon substrate 101 and the reflective layer 112. A method of patterning the metal layer 106 and the barrier metal material layer 105 includes forming a patterned photoresist layer (not shown) on the silicon substrate 101 and performing an etching process with use of the patterned photoresist layer as a mask.

In an embodiment of the invention, the reflective layer 112 is merely formed on the first insulating layer 104 on the sidewall of each of the recesses 103, as indicated in FIG. 1C. However, in another embodiment (not shown), the reflective layer 112 may be further extended to cover a top corner of each of the recesses 103.

It should be mentioned that a material of the conventional reflective layer is different from that of the positive electrode and the negative electrode. For instance, the reflective layer is made of aluminum, and the positive and negative electrodes are made of gold. Therefore, at least two patterning steps are required to form the reflective layer, the positive electrode, and the negative electrode according to the related art. Nonetheless, the reflective layer, the positive electrode, and the negative electrode can be simultaneously defined by performing only one patterning step in the invention; thus, the manufacturing process can be simplified, and the manufacturing costs can be lowered down.

From another perspective, the first electrode 108, the second electrode 110, and the reflective layer 112 are all made of silver with great reflectivity. Thereby, the light loss of the LED can be reduced, and the light extraction efficiency can be enhanced.

With reference to FIG. 1D, a cutting process is performed on the silicon substrate 101 to form a plurality of silicon bases 102. An outer sidewall of each of the silicon bases 102 is coated with a second insulating layer 114. The material of the first insulation layer 104 is different from the material of the second insulation layer 114. The material of the second insulation layer 114 can be a heat-dissipating, insulating glue, e.g., a white glue. So far, the silicon submount 100 of individual LED is completely formed.

The structure of the silicon submount for the LED is described below with reference to FIG. 1D. In the invention, the silicon submount 100 for the LED includes the silicon base 102, the first insulating layer 104, the barrier metal layer 107, the first electrode 108, the second electrode 110, the reflective layer 112, and the second insulating layer 114.

The silicon base 102 has the upper surface 101a and the lower surface 101b, and the recess 103 is located at the upper surface 101a. The first insulating layer 104 covers the upper surface 101a and the lower surface 101b of the silicon base 102. The first electrode 108 and the second electrode 110 are disposed on the first insulating layer 104 on a bottom of the recess 103. The reflective layer 112 is disposed on the first insulating layer 104 on a sidewall of the recess 103. The first electrode 108, the second electrode 110, and the reflective layer 112 are separated from one another and formed by the same material. The barrier metal layer 107 is disposed between the silicon base 102 and the first electrode 108, between the silicon base 102 and the second electrode 110, and between the silicon base 102 and the reflective layer 112. The second insulating layer 114 is located on the outer sidewall of the silicon base 102.

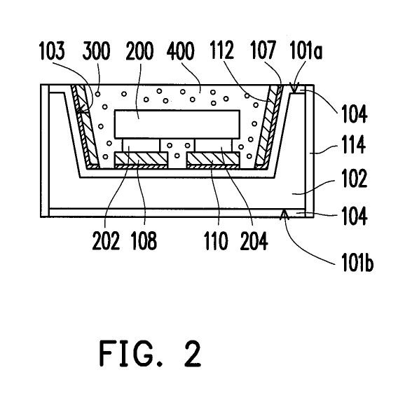

FIG. 2 is a schematic cross-sectional view illustrating an LED package structure according to an embodiment of the invention.

With reference to FIG. 2, the LED package structure of the invention includes the aforesaid silicon submount 100, an LED chip 200, phosphor powder 300, and a sealant 400. The LED chip 200 has a positive electrode 202 and a negative electrode 204 that are located on the same surface. Besides, the LED chip 200 is flip-chip bonded to the silicon submount 100. Here, the positive electrode 202 of the LED chip 200 is directly fused with the first electrode 108 (acting as the positive electrode) of the silicon submount 100, and the negative electrode 204 of the LED chip 200 is directly fused with the second electrode 110 (acting as the negative electrode) of the silicon submount 100. The recess 103 is filled with the sealant 400 that is doped with the phosphor powder 300, and the sealant 400 covers the LED chip 200.

In an embodiment of the invention, the LED chip 200 is a blue LED chip, for instance, and the phosphor powder 300 is yellow phosphor powder, for instance. Thereby, the LED package structure can emit white light for the purpose of illumination.

In light of the foregoing, each silicon base described in the embodiments of the invention is made of the material with favorable heat dissipation capacity, and the upper and lower surfaces of the silicon base are covered by the insulating, heat-dissipating layer that is made of the material with favorable thermal conductivity, such as aluminum nitride, aluminum oxide, or silicon nitride. Accordingly, the formed silicon submount can well dissipate heat, which leads to the improvement of the device performance.

Additionally, in the silicon submount described in the embodiments of the invention, a silver material with high reflectivity is applied to simultaneously define the first electrode, the second electrode, and the reflective layer, so as to simplify the manufacturing process, lower the manufacturing costs, and reduce the light loss of the LED.

Moreover, in the silicon submount described in the embodiments of the invention, the horizontal design of the positive and negative electrodes may be combined with the design of the flip-chip LED. Meanwhile, the positive electrode and the negative electrode of the silicon submount can be directly fused with the positive electrode and the negative electrode of the LED, and thus no additional costs on adhesives are required.

It will be apparent to those skilled in the art that various modifications and variations can be made to the structure of the invention without departing from the scope or spirit of the disclosure. In view of the foregoing, it is intended that the disclosure cover modifications and variations of this invention provided they fall within the scope of the following claims and their equivalents.

What is claimed is:

1. A silicon submount for a light emitting diode, comprising:
a silicon base having an upper surface and a lower surface, a recess being disposed at the upper surface;
a first insulating layer covering the upper surface and the lower surface of the silicon base;
a first electrode and a second electrode disposed on the first insulating layer on a bottom of the recess; and
a reflective layer disposed on the first insulating layer on a sidewall of the recess,
wherein the first electrode, the second electrode, and the reflective layer are separated from one another, and a material of the first electrode, a material of the second electrode, and a material of the reflective layer are the same.

2. The silicon submount for the light emitting diode as recited in claim 1, wherein a thermal conductivity of the first insulating layer is greater than 15 W/mk.

3. The silicon submount for the light emitting diode as recited in claim 2, wherein a material of the first insulating layer comprises aluminum oxide, aluminum nitride, or silicon nitride.

4. The silicon submount for the light emitting diode as recited in claim 1, wherein the material of the first electrode, the material of the second electrode, and the material of the reflective layer comprise silver.

5. The silicon submount for the light emitting diode as recited in claim 1, further comprising a barrier metal layer disposed between the silicon base and the first electrode, between the silicon base and the second electrode, and between the silicon base and the reflective layer.

6. The silicon submount for the light emitting diode as recited in claim 5, wherein a material of the barrier metal layer comprises titanium tungsten/copper.

7. The silicon submount for the light emitting diode as recited in claim 1, further comprising a second insulating layer disposed on an outer sidewall of the silicon base.

8. The silicon submount for the light emitting diode as recited in claim 7, wherein a material of the first insulating layer is different from a material of the second insulating layer.

9. A method of forming a silicon submount for a light emitting diode, comprising:
providing a silicon substrate, wherein the silicon substrate has an upper surface and a lower surface;
forming a plurality of recesses at the upper surface of the silicon substrate;
forming a first insulating layer on the upper surface and the lower surface of the silicon substrate;
forming a metal layer on the upper surface of the silicon substrate; and
patterning the metal layer to form a first electrode and a second electrode on the first insulating layer on a bottom of each of the recesses and to form a reflective layer on the first insulating layer on a sidewall of each of the recesses.

10. The method of forming the silicon submount for the light emitting diode as recited in claim 9, wherein a thermal conductivity of the first insulating layer is greater than 15 W/mk.

11. The method of forming the silicon submount for the light emitting diode as recited in claim 10, wherein a material of the first insulating layer comprises aluminum oxide, aluminum nitride, or silicon nitride.

12. The method of forming the silicon submount for the light emitting diode as recited in claim 10, wherein a method of forming the first insulating layer comprises performing a low pressure chemical vapor deposition process or a sputtering process.

13. The method of forming the silicon submount for the light emitting diode as recited in claim 9, further comprising, after patterning the metal layer,
performing a cutting process on the silicon substrate to form a plurality of silicon bases; and
coating a second insulating layer on an outer sidewall of each of the silicon bases.

14. The method of forming the silicon submount for the light emitting diode as recited in claim 13, wherein a material of the first insulating layer is different from a material of the second insulating layer.

15. The method of forming the silicon submount for the light emitting diode as recited in claim 9, wherein a method of forming the metal layer comprises performing a multi-step plating process.

16. The method of forming the silicon submount for the light emitting diode as recited in claim 9, wherein a material of the metal layer comprises silver.

17. The method of forming the semiconductor structure as claimed in claim 9, further comprising, after forming the first insulating layer and before forming the metal layer, forming a barrier metal material layer on the upper surface of the silicon substrate.

18. The method of forming the silicon submount for the light emitting diode as recited in claim 17, wherein a material of the barrier metal material layer comprises titanium tungsten/copper.
